(19) United States
(12) Patent Application Publication
(10) Pub. No.: US 2010/0098920 A1
(43) Pub. Date: Apr. 22, 2010

(54) DEVICE HOUSING AND METHOD FOR MAKING THE SAME

(75) Inventors: QIN-ZHENG HOU, Shenzhen City (CN); YAN-MIN WANG, Shenzhen City (CN); GANG HUANG, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignees: SHENZHEN FUTAIHONG PRECISION INDUSTRY CO., LTD., ShenZhen City (CN); FIH (HONG KONG) LIMITED, Kowloon (HK)

(21) Appl. No.: 12/557,693

(22) Filed: Sep. 11, 2009

(30) Foreign Application Priority Data
Oct. 17, 2008 (CN) 200810304967.3

(51) Int. Cl. B32B 3/00; B05D 5/12; C23C 14/24

(52) U.S. Cl. 428/201; 427/258; 204/192.15

(57) ABSTRACT

A device housing, comprising: a plastic substrate; a base paint layer formed on one surface of the substrate; a vacuum coated layer formed on the base paint layer, the vacuum coated layer having a metallic appearance; a transparent middle paint layer formed on the vacuum coated layer; a pattern layer formed on parts of the middle paint layer, the pattern layer having a predetermined pattern; and a transparent top paint layer formed on the surface of the pattern layer and the parts of the middle paint layer not covered by the pattern layer, the top paint layer being made of a paint having a soft tactility. A method for making the present device housing is provided.

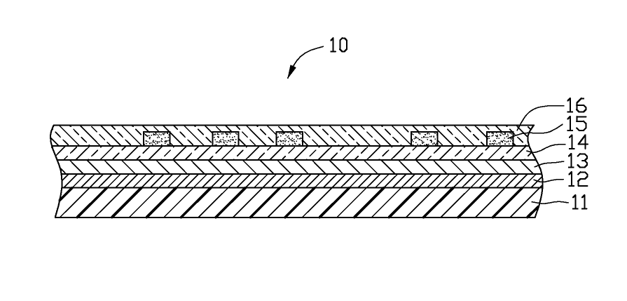

### BACKGROUND

1. Technical field

The present disclosure relates to device housings, particularly to a device housing with a metallic appearance and a soft tactility for electronic devices and a method for making the same.

2. Description of related art

Electronic devices often have decorative housings to attract consumers. Housings molded by plastic materials are usually electroplated with a metallic coating to create an attractive metallic appearance. However, electroplating creates wastewater which is not environmental friendly and cost effective. Moreover, the electroplated metallic coating may have only a rigid tactility.

Another method for forming a metallic coating on a plastic article is to spray paint the plastic article with a metallic paint. However, the metallic paint cannot present a real metallic appearance.

Therefore, there is room for improvement within the art.

### BRIEF DESCRIPTION OF THE DRAWING

Many aspects of the device housing and method for fabricating the device housing can be better understood with reference to the following drawing. The components in the drawing are not necessarily to scale, the emphasis instead being placed upon clearly illustrating the principles of the present device housing and the method for fabricating the device housing. Moreover, in the drawing, like reference numerals designate corresponding parts throughout the following view.

The figure is a cross-section view of device housing according to an exemplary embodiment.

### DETAILED DESCRIPTION OF THE EXEMPLARY EMBODIMENTS

Referring to the figure, an exemplary device housing 10 is used for mobile phones, laptop computers, cameras, or game consoles. The device housing 10 includes a plastic substrate 11, a base paint layer 12, a vacuum coated layer 13, a transparent middle paint layer 14, a pattern layer 15 and a transparent top paint layer 16.

The base paint layer 12 is directly formed on one surface of the plastic substrate 11. The vacuum coated layer 13 has a metallic appearance and is formed on the base paint layer 12. The vacuum coated layer 13 can be formed by a metallic material selected from a group consisting of indium, aluminum, titanium, tin, chromium, aurum, vanadium, stainless steel, and indium-tin alloy. Alternatively, the vacuum coated layer 13 can be a non-metallic material having a metallic appearance selected from a group consisting of titanium carbide, titanium nitride, titanium oxide, and aluminum oxide. The middle paint layer 14 is formed on the vacuum coated layer 13. The middle paint layer 14 can be painted with a colorless paint or a colorized paint. The pattern layer 15 is formed on parts of the middle paint layer 14. The pattern layer 15 has a predetermined pattern and may be made of colorized ink. The top paint layer 16 is formed on the surface of the pattern layer 15 and the parts of the middle paint layer 14 not covered by the pattern layer 15. The top paint layer 16 is made of paint having a soft tactility such as acrylic lacquer, or polyurethane lacquer.

An exemplary method for making the device housing 10 may include the following steps.

A plastic substrate 11 is provided. The plastic substrate 11 can be molded by a plastic such as polycarbonate (PC), polyethylene (PE), polymethyl methacrylate (PMMA), etc.

A base paint layer 12 is formed on one surface of the plastic substrate 11 for example, by spray painting. The base paint layer 12 can improve the smoothness of the surface of the plastic substrate 11. Accordingly, the subsequently formed vacuum coated layer 13 can have a glossy appearance. Moreover, the base paint layer 12 can improve the adhesion for bonding with the vacuum coated layer 13.

A vacuum coated layer 13 with a metallic appearance is formed on the base paint layer 12 by implementing a vacuum coating method such as vacuum evaporating or sputtering. The target used to form the vacuum coated layer 13 can be made of metallic material or non-metallic material having a metallic appearance as previously mentioned above. When the device housing 10 is used for a communication device (e.g., mobile phone), the vacuum coated layer 13 should be nonconductive by choosing a non-conductive target material and controlling the thickness of the vacuum coated layer 13 in a proper range that does not unduly effect communication signals.

A transparent middle paint layer 14 is formed on the vacuum coated layer 13. The middle paint layer 14 can be colorless or include different color dyes therein. The middle paint layer 14 can protect the vacuum coated layer and strengthen the adhesive force for the subsequent top paint layer 16.

A pattern layer 15 is formed on parts of the vacuum coated layer 13 by, e.g., screen printing or pad printing. The pattern layer 15 may have any predetermined pattern and may be made of colored ink.

A transparent top paint layer 16 is formed on the surface of the pattern layer 15 and the parts of the surface of the middle paint layer 14 not covered by the pattern layer 15. The top paint layer 15 is made of a paint having a soft tactility such as acrylic lacquer, or polyurethane lacquer.

It should be understood, prior to the forming of the base paint coating, a de-dusting treatment may be implemented.

It should be understood, however, that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A device housing, comprising:
a plastic substrate;
a base paint layer formed on a surface of the substrate;
a vacuum coated layer formed on the base paint layer, the vacuum coated layer having a metallic appearance;
a transparent middle paint layer formed on the vacuum coated layer;
a pattern layer formed on parts of the middle paint layer; and
a transparent top paint layer formed on the surface of the pattern layer and the parts of the middle paint layer not covered by the pattern layer, the top paint layer being made of a paint having a soft tactility.

2. The device housing as claimed in claim 1, wherein the vacuum coated layer is formed by a metallic material.

3. The device housing as claimed in claim 2, wherein the metallic material is selected from a group consisting of indium, aluminum, titanium, tin, chromium, aurum, vanadium, stainless steel and indium-tin alloy.

4. The device housing as claimed in claim 1, wherein the vacuum coated layer is formed by a non-metallic material.

5. The device housing as claimed in claim 4, wherein the non-metallic material is selected from a group consisting of titanium carbide, titanium nitride, titanium oxide, and aluminum oxide.

6. The device housing as claimed in claim 1, wherein the middle paint layer is painted with a colorless paint or a colorized paint.

7. The device housing as claimed in claim 1, wherein the pattern layer is made of a colorized ink.

8. The device housing as claimed in claim 1, wherein the top paint layer is made of acrylic lacquer or polyurethane lacquer.

9. A method for making a device housing, comprising the steps of:
providing a plastic substrate;
forming a base paint layer on a surface of the substrate;
forming a vacuum coated layer on the base paint layer, the vacuum coated layer having a metallic appearance;
forming a transparent middle paint layer on the vacuum coated layer;
forming a pattern layer on part of the middle paint layer; and
forming a transparent top paint layer on the surface of the pattern layer and the parts of the middle paint layer not covered by the pattern layer, the top paint layer made of a paint having soft tactility.

10. The method for making a device housing as claimed in claim 9, wherein the vacuum coated layer is formed by vacuum evaporating or vacuum sputtering.

11. The method for making a device housing as claimed in claim 10, wherein the target for forming the vacuum coated layer is made of a metallic material.

12. The method for making a device housing as claimed in claim 11, wherein the metallic material is selected from indium, aluminum, titanium, tin, chromium, aurum, vanadium, stainless steel and indium-tin alloy.

13. The method for making a device housing as claimed in claim 9, wherein the target for forming the vacuum coated layer is made of a metallic material.

14. The method for making a device housing as claimed in claim 13, wherein the metallic material is selected from titanium carbide, titanium nitride, titanium oxide, and aluminum oxide.

15. The method for making a device housing as claimed in claim 9, wherein the middle paint layer is painted with a colorless paint or a colorized paint.

16. The method for making a device housing as claimed in claim 9, wherein the pattern layer is made of a colorized ink.

17. The method for making a device housing as claimed in claim 16, wherein the pattern layer is formed by screen printing or pad printing.

18. The method for making a device housing as claimed in claim 9, wherein the top paint layer is made of acrylic lacquer or polyurethane lacquer.
